(19) United States
(12) Patent Application Publication
(10) Pub. No.: US 2026/0366152 A1
(43) Pub. Date: Nov. 19, 2026

(54) ATOMIC LAYER DEPOSITION APPARATUS

(71) Applicant: ISAC RESEARCH INC., Daejeon (KR)

(72) Inventors: Tae Ho YOON, Daejeon (KR); Hyung Sang PARK, Daejeon (KR); Young Duck TAK, Daejeon (KR)

(73) Assignee: ISAC RESEARCH INC., Daejeon (KR)

(21) Appl. No.: 19/653,255

(22) Filed: Apr. 21, 2026

(30) Foreign Application Priority Data
May 16, 2025 (KR) 10-2025-0064067

(51) Int. Cl. C23C 16/455; C23C 16/44; C23C 16/458; C23C 16/48

(52) U.S. Cl. CPC C23C 16/45544; C23C 16/4408; C23C 16/45565; C23C 16/4584; C23C 16/481

(57) ABSTRACT

An atomic layer deposition apparatus includes a process chamber including a body defining a reaction region and a top lid coupled to the body; a substrate support unit disposed in the process chamber and configured to support a plurality of substrates thereon; a gas injection unit disposed in the process chamber and facing the substrate support unit, the gas injection unit including a source gas injector configured to inject a source gas, a reaction gas injector configured to inject a reaction gas, and at least one purge gas injector configured to inject a purge gas; and at least one laser module coupled to the gas injection unit or the top lid and configured to emit a laser beam onto the substrates supported on the substrate support unit.

### CROSS-REFERENCE TO RELATED PATENT APPLICATION

The present application claims priority under 35 U.S.C. §119(a) to Korean Patent Application No. 10-2025-0064067, filed in the Korean Intellectual Property Office on May 16, 2025, the entire contents of which application is incorporated herein by reference.

### STATEMENT REGARDING SPONSORED RESEARCH OR DEVELOPMENT

The research and development of the present disclosure were conducted with the support of Korea Planning & Evaluation Institute of Industrial Technology (KEIT) grant funded by the Ministry of Trade, Industry and Energy (MOTIE) (Project No. 20018106, Detailed Project identifier: 1415187290).

### BACKGROUND

### 1. Field of the Disclosure

The present disclosure relates to a semiconductor manufacturing apparatus, and more particularly, to an atomic layer deposition (ALD) apparatus for thin film deposition on a substrate.

### 2. Description of the Related Art

Recently, due to high integration of semiconductor devices, a high degree of precision is required in the manufacturing process of semiconductor devices. To manufacture a semiconductor device, various substrate processing operations are performed in a substrate processing apparatus in a vacuum atmosphere. For example, a process of loading a substrate into a process chamber and depositing a thin film on the substrate may be performed. The substrate is supported by a susceptor installed in the process chamber, and a process gas may be injected onto the substrate through a gas supply unit installed on an upper portion of the susceptor to deposit the thin film on the substrate.

Unlike a single-wafer time-division type atomic layer deposition (ALD) apparatus, a space-division type ALD apparatus is capable of simultaneously forming thin films on a plurality of substrates by loading the substrates on a susceptor and supplying process gases onto the substrates while rotating the susceptor. In this regard, the space-division type ALD apparatus is advantageous in terms of productivity. However, in the space-division type ALD apparatus, since thin film formation is performed at a relatively low temperature, an additional heat treatment process or plasma treatment process is required, thereby reducing productivity.

### SUMMARY OF THE DISCLOSURE

According to an embodiment of the present disclosure, an atomic layer deposition apparatus according to an aspect of the present disclosure for achieving the technical object includes: a process chamber including a body defining a reaction region and a top lid coupled to the body; a substrate support unit disposed in the process chamber such that a plurality of substrates are supported thereon; a gas injection unit installed in the process chamber and disposed to face the substrate support unit, the gas injection unit including a source gas injector configured to inject a source gas, a reaction gas injector configured to inject a reaction gas, and at least one purge gas injector configured to inject a purge gas; and at least one laser module coupled to the gas injection unit or the top lid and configured to emit a laser beam onto the substrates supported on the substrate support unit.

### BRIEF DESCRIPTION OF THE DRAWINGS

The above and other features and advantages of the present disclosure will become more apparent by describing in detail embodiments thereof with reference to the attached drawings in which:

FIG. 1 is a schematic cross-sectional view illustrating an atomic layer deposition apparatus according to an embodiment of the present disclosure.

FIG. 2 is a schematic bottom view of a gas injection unit in the atomic layer deposition apparatus of FIG. 1.

FIG. 3 is a schematic bottom view illustrating modified examples of a gas injection unit in the atomic layer deposition apparatuses according to embodiments of the present disclosure.

FIG. 4 is a schematic cross-sectional view illustrating an atomic layer deposition apparatus according to another embodiment of the present disclosure.

### DETAILED DESCRIPTION OF THE DISCLOSURE

Hereinafter, preferred embodiments of the present disclosure are described in detail with reference to the accompanying drawings.

Embodiments of the present disclosure are provided to more fully describe the present disclosure to those skilled in the art, and the following embodiments may be modified in various other forms, and the scope of the present disclosure is not limited to the following embodiments. Rather, these embodiments are provided so that this disclosure will be thorough and complete, and will fully convey the concept of the present disclosure to those skilled in the art. In addition, thicknesses or sizes of layers in the drawings are exaggerated for convenience and clarity of description.

An object of the present disclosure is to provide an atomic layer deposition (ALD) apparatus capable of improving productivity while improving the quality of a thin film by performing a deposition process and a heat treatment process in a single apparatus to solve various problems including the above problems. However, the above object is entirely illustrative, and the scope of the present disclosure is not limited thereby.

According to the atomic layer deposition apparatus of the embodiments of the present disclosure as described above, by providing the laser module in the process chamber, a deposition process and a heat treatment process may be continuously performed in the process chamber, so that productivity may be improved while the quality of a thin film is improved. Of course, the scope of the present disclosure is not limited by these effects.

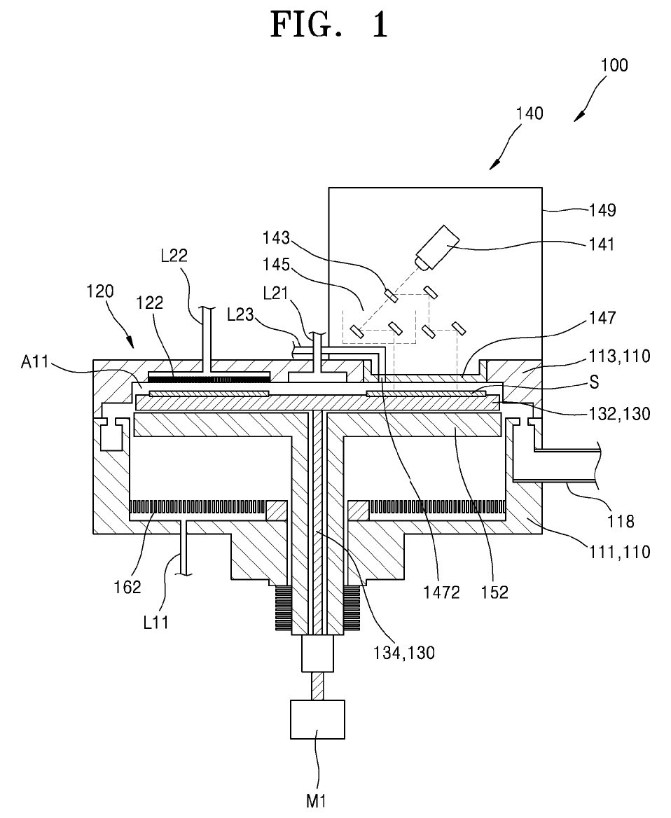

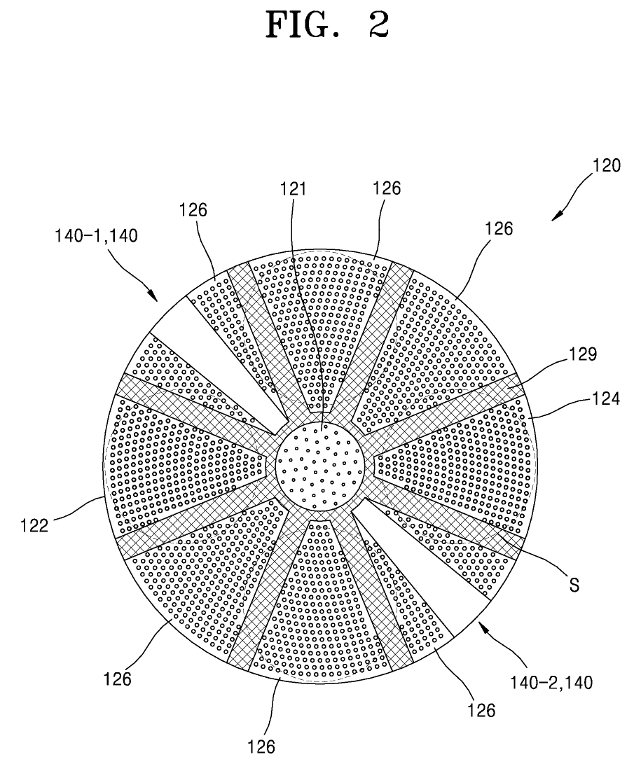

FIG. 1 is a schematic cross-sectional view illustrating an atomic layer deposition apparatus 100 according to an embodiment of the present disclosure, and FIG. 2 is a schematic bottom view of a gas injection unit 120 in the atomic layer deposition apparatus 100 of FIG. 1.

Referring to FIGS. 1 and 2, the atomic layer deposition apparatus 100 may include a process chamber 110, a gas injection unit 120, a substrate support unit 130, and at least one laser module 140.

The process chamber 110 may include a reaction region A11 for processing a substrate S. The process chamber 110 may be provided in various shapes, and a plurality of parts may be assembled to form the process chamber 110. For example, the process chamber 110 may include a body 111 defining the reaction region A11 and a top lid 113 coupled to the body 111.

Furthermore, the process chamber 110 is configured to maintain an airtight environment, and may be connected to a vacuum pump (not shown) through an exhaust line 118 to exhaust a process gas in the reaction region A11 and control a vacuum level in the reaction region A11. For example, the exhaust line 118 may be installed on a side portion of the process chamber 110, and optionally, may be additionally installed on a lower portion of the process chamber 110 to induce downward exhaust. In addition, an upward exhaust line 129 may optionally be further disposed in the top lid 113 or the gas injection unit 120 to induce upward exhaust.

The substrate support unit 130 may be installed in the process chamber 110 such that a plurality of substrates S are supported thereon. For example, the substrate support unit 130 may include a plate 132 for supporting the substrates S, and a shaft 134 connected to the plate 132 to extend outside the process chamber 110 to move the plate 132 vertically (upward and downward) or to rotate the plate 132.

The shape of the plate 132 generally corresponds to the shape of the substrate S, but is not limited thereto, and may be provided in various shapes so that the substrate S can be stably supported thereon. For example, a plurality of seating recesses (not shown) may be formed on the plate 132 of the substrate support unit 130 such that the substrates S are seated therein. Because the substrate support unit 130 is configured to seat the substrates S thereon, the substrate support unit 130 may also be referred to as a substrate seating unit, a substrate holder, a susceptor, or the like.

The substrate support unit 130 is supported through the shaft 134 and may be moved vertically or rotated through the shaft 134. For example, a motor unit M1 may be connected to the shaft 134, and the shaft 134 may receive driving power to move the shaft vertically or rotating power from the motor unit M1. Furthermore, a bellows tube (not shown) may be connected between the shaft 134 and the process chamber 110 to maintain airtightness.

In some embodiments, a heater unit 152 for heating the substrates S may be disposed adjacent to the substrate support unit 130. For example, the heater unit 152 may be disposed under the plate 132 to heat the substrate support unit 130 and the substrates S. The heater unit 152 may receive power from the outside of the process chamber 110.

The gas injection unit 120 may be installed in the process chamber 110 and disposed to face the substrate support unit 130. The gas injection unit 120 may inject process gases supplied from the outside of the process chamber 110 into the reaction region A11 to supply the process gases onto the substrates S. For example, the gas injection unit 120 may be coupled to an upper portion of the process chamber 110, for example, the top lid 113.

For example, the gas injection unit 120 may include a source gas injector 122 configured to inject a source gas, a reaction gas injector 124 configured to inject a reaction gas, and at least one purge gas injector 126 configured to inject a purge gas. Injection holes for injecting a process gas may be respectively formed in the source gas injector 122, the reaction gas injector 124, and the purge gas injector 126. The source gas functions as a precursor during thin film deposition, and the reaction gas may be used to form a thin film by reacting with the source gas. The purge gas may include an inert gas or a non-reactive gas and may be used to purge a residual gas or a byproduct in the process chamber 110.

In some embodiments, as shown in FIG. 2, the source gas injector 122, the reaction gas injector 124, and the purge gas injector 126 may be radially arranged along a circumference in the gas injection unit 120. Depending on design requirements, one or a plurality of the source gas injector 122, the reaction gas injector 124, and the purge gas injector 126 may be provided. For example, a plurality of the reaction gas injectors 124 and a plurality of the purge gas injectors 126 may be disposed in the gas injection unit 120, and furthermore, the purge gas injectors 126 may be respectively disposed between the source gas injector 122 and the reaction gas injectors 124.

In some embodiments, a central gas injection unit 121 may be installed in a center of the gas injection unit 120. Injection holes for injecting a purge gas for preventing mixing of process gases, for example, mixing of a source gas and a reaction gas, may be formed in the central gas injection unit 121. For example, the purge gas may include an inert gas.

The gas injection unit 120 may receive process gases through a gas supply line disposed on an upper portion of the process chamber 110. For example, the gas supply line may include a source gas supply line L22 for supplying a source gas to the source gas injector 122, and purge gas supply lines L21 and L23 for supplying a purge gas to the purge gas injectors 126. In the gas injection unit 120, inlet holes into which the process gases supplied through the gas supply line are introduced may be formed in an upper portion thereof.

In some embodiments, the upward exhaust line 129 may be installed between the source gas injector 122 and the purge gas injectors 126 and between the reaction gas injector 124 and the purge gas injectors 126 in the gas injection unit 120. The upward exhaust line 129 may be used to exhaust a gas in the process chamber 110 upwardly or may exhaust a gas injected from the source gas injector 122, the reaction gas injector 124, and the purge gas injectors 126 and flowing laterally, thereby preventing gas mixing therebetween.

In some embodiments, a lower shower head 162 may be installed on a bottom surface of the process chamber 110 to supply a lower purge gas to a lower portion of the plate 132. Furthermore, a lower purge gas line L11 for supplying the lower purge gas to the lower shower head 162 may be installed on the bottom surface of the process chamber 110. The lower purge gas supplied to the lower shower head 162 through the lower purge gas line L11 may be injected toward a lower portion of the plate 132 of the substrate support unit 130. This lower purge gas may function to prevent a source gas or reaction gas on the plate 132 from flowing to a lower portion of the plate 132.

According to the atomic layer deposition apparatus 100, while the source gas injector 122 injects the source gas, the reaction gas injectors 124 inject the reaction gas, and the purge gas injectors 126 inject the purge gas, the substrate support unit 130 may be rotated so that the source gas, the purge gas, the reaction gas, and the purge gas are sequentially supplied onto the substrates S. Therefore, according to the atomic layer deposition apparatus 100, a thin film may be simultaneously deposited on the substrates S in a spatially separated manner.

Meanwhile, the laser module 140 may be coupled to the process chamber 110 to emit a laser beam onto the substrates S on the substrate support unit 130. For example, the laser module 140 may be coupled to the gas injection unit 120 or the top lid 113. The laser module 140 may be provided to heat the substrates S and/or heat process gases during atomic layer deposition.

When the substrate support unit 130 is rotated, the substrates S may sequentially receive a laser beam from the laser module 140. Accordingly, even when the substrate support unit 130 is maintained at a relatively low temperature, optical energy may be instantaneously supplied to surfaces of the substrates S using the laser module 140 to provide reaction energy. Therefore, by using the laser module 140, while maintaining the substrates S at a relatively low temperature, by supplying laser energy onto surfaces of the substrates S, a thin film may be deposited on the substrates S, and a thermal shock applied to the substrates S may be reduced.

In addition, the laser module 140 may provide laser energy required to change deposition characteristics or thin film properties during thin film deposition on the substrates S, and may adjust the applied laser energy according to required characteristics. Accordingly, the laser module 140 may adjust the laser energy and/or a pulse duration. Furthermore, in consideration of an angular velocity of the plate 132 due to rotation of the substrate support unit 130 and a linear velocity at different positions on the substrates S, the pulse duration may be adjusted.

For example, the laser module 140 may include a laser source 141, a beam splitter 143, and a plurality of mirrors 145. The laser source 141 may emit a laser beam, and the beam splitter 143 may be provided to split the laser beam emitted from the laser source 141. For example, the laser source 141 may emit a high-energy pulsed laser, such as a KrF excimer laser or an Nd:YAG laser.

The mirrors 145 may be provided to redirect and scan the laser beam split through the beam splitter 143. For example, the mirrors 145 may be disposed so that the laser beam can be swept on the substrates S and may include scanning mirrors or galvanometer mirrors. Furthermore, a focusing lens (not shown) for focusing a laser beam may be further added below the mirrors 145.

In some embodiments, a plurality of beam splitters 143 may be provided to accommodate large-area substrates S, and a plurality of mirrors 145 may be disposed below each beam splitter 143. Accordingly, even when the diameter of the substrates S increases, the laser beam may be uniformly irradiated onto the substrates S.

In some embodiments, the laser module 140 may further include a housing 149 covering the laser source 141, the beam splitter 143, and the plurality of mirrors 145. Furthermore, a light transmission window 147 through which a laser beam is transmitted may be installed on a bottom surface of a portion of the purge gas injector 126 in which the laser module 140 is installed. At least one through-hole 1472 into which the purge gas supplied from the purge gas line L23 is injected may be formed in the light transmission window 147. A material having high laser transmittance may be selected for the light transmission window 147, and further, an anti-reflection coating (ARC) may be formed on a surface thereof to reduce reflectance. Accordingly, loss of laser energy due to absorption or reflection in the light transmission window 147 may be reduced, and contamination of the light transmission window 147 may be reduced.

In some embodiments, the laser module 140 may be installed in some of the purge gas injectors 126. The purge gas line L23 may supply a purge gas to the purge gas injectors 126 and further may supply a purge gas to the laser module 140. The purge gas supplied to the laser module 140 may prevent process gases, for example, a source gas and a reaction gas, supplied to the reaction region A11 from flowing into the laser module 140. However, in order to prevent plasma discharge of a process gas or a purge gas caused by a photoelectric effect during an operation of the laser module 140, supply of a process gas, for example, a source gas, a reaction gas, and/or a purge gas, may be selectively stopped or reduced during the operation of the laser module 140.

In some embodiments, as shown in FIG. 2, two laser modules 140 may be respectively installed in two purge gas injectors 126. For example, a first laser module 140-1 may be installed in a purge gas injector 126 between the source gas injector 122 and the reaction gas injector 124, and a second laser module 140-2 may be disposed in a purge gas injector 126 located between adjacent reaction gas injectors 124.

For example, the first laser module 140-1 may be disposed adjacent to the source gas injector 122 to instantaneously increase a surface temperature of the substrates S to improve an adsorption characteristic of a source gas, that is, a precursor, on the substrates S in each cycle of atomic layer deposition. The second laser module 140-2 may be disposed adjacent to the reaction gas injector 124 to instantaneously increase a surface temperature of the substrates S to increase a reaction rate between a source gas adsorbed on the substrates S and a reaction gas.

As another example, a laser beam may be emitted from only one of the first laser module 140-1 and the second laser module 140-2, while the other remains inactive. In this case, depending on whether improvement of adsorption characteristics of the source gas or enhancement of the reaction rate between the source gas and the reaction gas is required, one of the first laser module 140-1 and the second laser module 140-2 may be selectively operated.

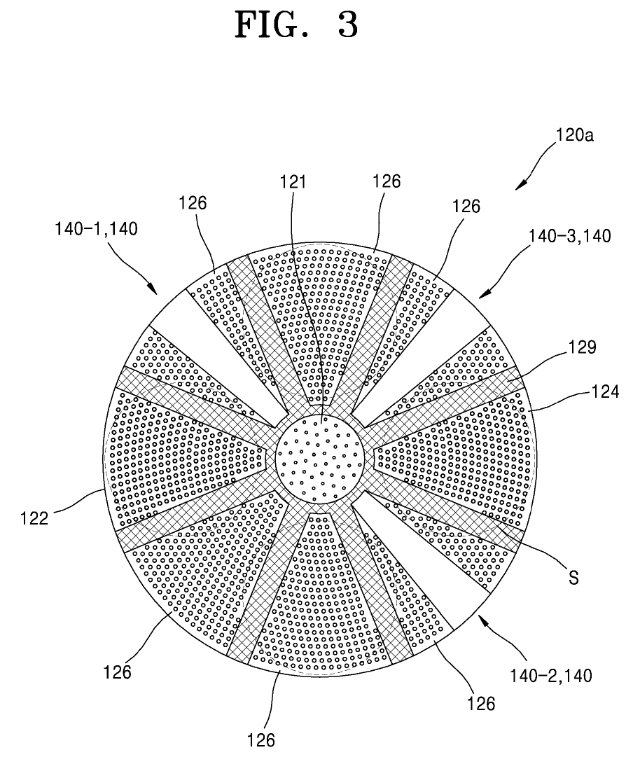

In some embodiments, as shown in FIG. 3, three laser modules 140 may be respectively installed in three purge gas injectors 126. For example, a first laser module 140-1 may be installed in a purge gas injector 126 located between the source gas injector 122 and the reaction gas injector 124, a second laser module 140-2 may be installed in a purge gas injector 126 located between adjacent reaction gas injectors 124, and a third laser module 140-3 may be installed in a purge gas injector 126 located between a purge gas injector 126 and a reaction gas injector 124.

For example, the first laser module 140-1 or the third laser module 140-3 may instantaneously increase the surface temperature of the substrates S to improve adsorption characteristics of the source gas, i.e., the precursor, in each atomic layer deposition cycle. The second laser module 140-2 may instantaneously increase the surface temperature of the substrates S to enhance the reaction rate between the source gas adsorbed on the substrates S and the reaction gas. Additionally, by further using the first laser module 140-1 or the third laser module 140-3, laser energy may be additionally supplied to the substrates S to improve properties of a thin film deposited on the substrates S, for example, crystallinity, durability, or other film characteristics.

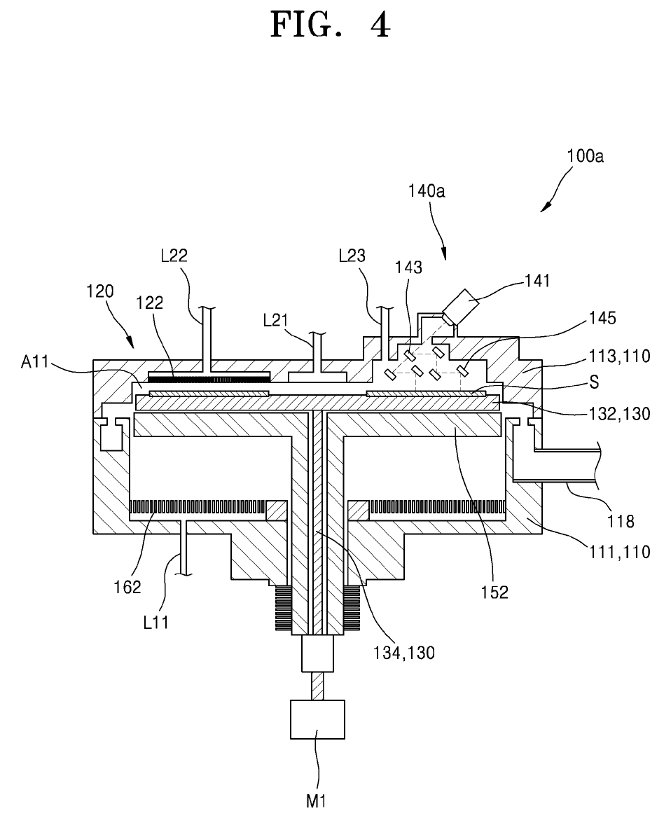

FIG. 4 is a schematic cross-sectional view illustrating an atomic layer deposition apparatus 100a according to another embodiment of the present disclosure. The atomic layer deposition apparatus 100a has partial components modified from those of the atomic layer deposition apparatus 100 of FIG. 1, and therefore, the embodiments may be described with reference to each other, and thus redundant descriptions are omitted for brevity.

Referring to FIG. 4, the atomic layer deposition apparatus 100a may include a laser module 140a. Unlike the laser module 140 of FIG. 1, the laser module 140a may not include the light transmission window 147. Accordingly, in the laser module 140a, the laser source 141 may emit a laser beam into the purge gas injector 126, and the beam splitter 143 and the mirrors 145 may be disposed within the purge gas injector 126, such that the laser beam passing through the beam splitter 143 and the mirrors 145 is emitted directly onto the substrate support unit 130 in a vacuum atmosphere without an additional light transmission window 147. Accordingly, energy loss of the laser beam due to transmission through the light transmission window 147 may be eliminated, thereby improving energy transfer efficiency.

In the above-described atomic layer deposition apparatuses 100 and 100a, the laser modules 140 and 140a are described as being installed in the purge gas injectors 126. However, in modified examples, the laser modules 140 and 140a may alternatively be installed in the source gas injector 122 or the reaction gas injector 124. In such a case, the laser modules 140 and 140a may emit a laser beam while the source gas injector 122 or the reaction gas injector 124 injects a source gas or a reaction gas. Alternatively, to prevent plasma discharge caused by a photoelectric effect, the laser beam may be emitted while injection of the source gas or reaction gas is temporarily stopped.

According to the above-described atomic layer deposition apparatuses 100 and 100a, the laser modules 140 and 140a are installed in the gas injection unit 120 or the top lid 113 to supply laser energy onto the substrates S in situ during an atomic layer deposition process within a vacuum atmosphere. Accordingly, while maintaining the substrates S at a temperature lower than a reaction temperature for atomic layer deposition, laser energy may be supplied during each deposition cycle to improve deposition characteristics or thin film properties.

While the present disclosure has been described with reference to the embodiments shown in the drawings, this is merely exemplary, and it will be understood by those skilled in the art that various modifications and equivalent other embodiments can be made therefrom. Therefore, the true technical scope of the present disclosure should be defined by the technical spirit of the appended claims.

What is claimed is:

1. An atomic layer deposition apparatus, comprising:
a process chamber including a body defining a reaction region and a top lid coupled to the body;
a substrate support unit disposed in the process chamber such that a plurality of substrates are supported thereon;
a gas injection unit installed in the process chamber and disposed to face the substrate support unit, the gas injection unit including a source gas injector configured to inject a source gas, a reaction gas injector configured to inject a reaction gas, and at least one purge gas injector configured to inject a purge gas; and
at least one laser module coupled to the gas injection unit or the top lid and configured to emit a laser beam onto the substrates supported on the substrate support unit.

2. The atomic layer deposition apparatus of claim 1, wherein each of the at least one laser module comprises:
a laser source configured to emit a laser beam;
a beam splitter configured to split the laser beam emitted from the laser source; and
a plurality of mirrors configured to redirect and emit the laser beam split through the beam splitter.

3. The atomic layer deposition apparatus of claim 1, further comprising a purge gas line configured to supply a purge gas to the at least one laser module.

4. The atomic layer deposition apparatus of claim 3, wherein the at least one laser module is installed in a portion of the at least one purge gas injector of the gas injection unit, and wherein the purge gas line is configured to supply the purge gas to the portion of the at least one purge gas injector and the at least one laser module.

5. The atomic layer deposition apparatus of claim 4, wherein a light transmission window through which a laser beam is transmitted is installed on a bottom surface of the portion of the at least one purge gas injector in which the at least one laser module is installed, and wherein at least one through-hole through which the purge gas supplied from the purge gas line is injected is formed in the light transmission window.

6. The atomic layer deposition apparatus of claim 1, wherein the substrate support unit includes:
a plate configured to support the substrates;
a shaft connected to the plate and extending outside the process chamber to move the plate vertically or to rotate the plate; and
a heater unit disposed beneath the plate.

7. The atomic layer deposition apparatus of claim 6, further comprising a lower shower head installed on a bottom surface of the process chamber to supply a lower purge gas to a lower portion of the plate, and wherein a lower purge gas line configured to supply the lower purge gas to the lower shower head is installed on the bottom surface of the process chamber.

8. The atomic layer deposition apparatus of claim 2, wherein the at least one laser module is installed on the top lid, wherein the beam splitter is installed in the top lid, and wherein the laser source is configured to emit the laser beam from outside the top lid to inside the top lid.

9. The atomic layer deposition apparatus of claim 1, wherein the at least one purge gas injector includes a plurality of purge gas injectors, and wherein the at least one laser module includes a plurality of laser modules disposed in some of the plurality of purge gas injectors.
